(19) United States
(12) Patent Application Publication
(10) Pub. No.: US 2008/0028278 A1
(43) Pub. Date: Jan. 31, 2008

(54) Circuit architecture protected against perturbations

(75) Inventor: Michael Nicolaidis, Saint Egreve (FR)

Correspondence Address: BASINSKI & ASSOCIATES, 113 SAN NICOLAS AVENUE, SANTA BARBARA, CA, 93109, US

(73) Assignee: iROC Technologies, Grenoble (FR)

(21) Appl. No.: 11/904,762

(22) Filed: Sep. 27, 2007

Related U.S. Application Data
(62) Division of application No. 10/492,294, filed on Apr. 8, 2004.

(30) Foreign Application Priority Data
Oct. 12, 2001 (FR) 0113241

(51) Int. Cl. G11C 29/00

(52) U.S. Cl. 714/768

(57) ABSTRACT

The invention concerns a digital circuit architecture including combinatorial circuits, and memory circuits. Systems for protection against different perturbations are used for different types of circuits based upon the functionality of the circuits.

### BACKGROUND OF THE INVENTION

1. Field of the Invention

The present invention relates to digital circuits protected against the effects of disturbances such as transitory disturbances resulting from external causes or from time faults linked to the circuit manufacturing.

2. Discussion of the Related Art

A transitory fault is generated by a local disturbance resulting for example from particle bombardings. The capacitances of the nodes and the supply voltages of modern integrated circuits being smaller and smaller, the charges present on the nodes become very small. Thus, the circuits become sensitive to smaller and smaller disturbances. The logic value of a node can be inverted by particles having very small powers. In past integrated circuit technologies, particles hitting the memory points were mostly the cause of logic faults. With the increased sensitivity of modern technologies, transitory pulses affecting a node of a combinatory circuit propagate to the memory point inputs (latches). At the same time, the increase in operating speeds increases the probability for a transitory pulse at the input of a latch to effectively be sampled thereby, resulting in a logic error.

A time fault results from the fact that, while a circuit element is normally designed to have a given response time, this time, because of a local manufacturing defect, may be longer than what has been provided by the designer. Thus, if a sampling is performed after the normal circuit response time, this sampling may occur while the circuit has not switched yet. Due to the increase in density and operating speed of modern integrated circuits, such faults are more and more current and very difficult to test with usual test programs and may thus remain in a circuit normally tested as being good.

Generally, a fault resulting from a transitory disturbance or from a manufacturing defect modifying the response time of a circuit element will be called a temporary fault, or simply, a fault.

Clearly, the occurrence of such faults may lead a logic circuit to providing erroneous results and memories to containing wrong data. Thus, it has been attempted to immunize circuits against faults. Intrinsically-protected circuits, or hardened circuits, may be used. Another technique to be sure to correct any error consists of triplicating each base unit and using a majority vote to select the correct result from among the three results provided by the three circuits, of course assuming that three identical circuits may not at a given time be affected by the same fault. Such systems, extremely heavy and expensive, have essentially been used for digital circuits comprising combinatory circuits or circuits comprising combinatory circuits and memories. For circuits comprising memories only, less expensive methods consisting of associating with each datum likely to be memorized an error-correction code have been developed. According to this principle, the data written into the memory are completed by a number of control bits (Hamming code, Reed Solomon code, etc.). To each reading is associated a checking of the coherence of the coding by a dedicated circuit which, if there is an error, locates it and corrects it.

Another general error-correction technique consists of simply using an error detection and back-up method. The system state is periodically memorized and relatively simple codes or duplication methods, such as described for example in French patent application 9903027 of Mar. 9, 1999, are used to detect whether a fault has occurred. When an error has been detected, the system operation is interrupted and the system is set back to the state that it had before the last back-up. When thus operating at the system level, very large back-ups of a great number of states must be made, which results in practice in making quite distant back-ups, and thus, in case there is a fault, in having to go back quite far behind.

### SUMMARY OF THE INVENTION

Generally, an object of the present invention is to simplify problems of protection of a logic circuit against disturbances.

To achieve this object, the present invention is essentially based on an analysis of the operation of the various elements of a system and provides adopting for the various parts of a system specific processings of protection against errors or error repairs. The minimum-cost solution will thus be chosen for each block. Each time it is possible—and performing this analysis is an aspect of the present invention—a detect and restart mechanism enabling correcting the errors generated by a transitory fault by repeating a small number of the most recent operations will be used. To avoid long interrupts, restart mechanisms operating over a small number of operating cycles are provided. The implementation of these mechanisms within the integrated circuit will enable systematic back-up of states appearing in the circuit during the last k operating cycles, k being a value chosen by the designer, greater than the number of cycles necessary to detect an error and generate an interrupt. According to cases, an operating cycle will be a clock cycle or an instruction execution cycle.

However, this principle cannot apply to all the parts of a circuit. For example, it should be noted that a value stored in a memory for more than k operating cycles, if it is corrupted by a fault, cannot be corrected by a restart operating over the last k operating cycles. Thus, for a memory that can store data for a duration longer than k operating cycles (hereafter, called a long-term memory), a fault immunization technique must be applied instead of a fault detection and a restart. An error detection and correction code may for example be used. Thus, a fault affecting a memory cell will be detected and corrected. Memorization cells hardened against transitory faults may also be used. The cost of use, in percents of the occupied surface area, for the error detection and correction codes, becomes very low for large memory arrays but may dramatically increase for small memories. Thus, preference will be given to large memory arrays and to memorization cells hardened against transitory faults for small memories or distributed memorization cells.

Regarding the combinatory parts, a restart will enable correcting the errors generated by a transitory fault. Thus, an error detection technique accompanied by a restart operating over the last k operating cycles may be used. However, if a combinatory circuit controls (addressing or read/write) a long-term memory part, a detect and restart technique will not enable correcting errors due to a transitory fault. Indeed, an error generated by such a circuit may induce an addressing error during a write operation and destroy a datum stored at this address for more than k operating cycles. Another fault having a similar consequence is a fault that starts a writing during a read cycle or during a cycle when the memory is not being accessed to. It should be noted that a writing of correct data at a bad address generates errors which are never detected by an error detection/ correction code since the written data are coded properly. Thus, a combinatory part controlling a memory storing data for a time period greater than k operating cycles must be protected by a fault immunization technique. Combinatory circuits concerned by this solution are, for example, a combinatory portion generating memory addresses or generating write/read signals, address decoders, etc.

Even for such circuits controlling long-term memories, it can be avoided to provide a heavy immunization by noting various particular cases.
An error on the write/read signals will have two polarities: error of read-instead-of-write type (1 instead of 0 on R/W) or of write-instead-of-read-type (0 instead of 1 on R/W). The second polarity is dangerous and must be avoided, while it will be enough to detect the first one and to trigger a restart to correct the generated errors.
Similarly, there are two types of errors on the outputs of an address decoder (lines or columns): an active output becomes inactive (error polarity 0 instead of 1), or one or several non-active outputs become active (error polarity 1 instead of 0). It can be again observed that the second polarity generates non-recoverable errors and must be avoided while it would be enough to detect the errors of the first polarity and to trigger a restart to be able to correct them. An immunization technique may thus be used for errors of a certain polarity while a detection and restart technique will be used for errors of opposite polarity.
In certain cases, for combinatory circuits controlling long-term memories, an error-detection technique may be used only to block the memory operation before a data destruction occurs. This principle may only be used if the operating delays of the memory and of the error detection mechanism are compatible with such a blocking.

Before the time of occurrence of a fault in a portion employing a detection mechanism and the time when the system is interrupted to trigger a restart, a given time (k operating cycles) elapses. During this time, to perform a restart, the content of the memorization points (latches, register sets, memories) which determine a state of the circuit before occurrence of the fault must be recovered, based on which all the successive operations may be properly repeated. For this purpose, a state-conservation mechanism (SCM) for each memorization portion (latches, register sets, memories), the state of which will be saved to be able to perform the restart of the circuit operation, will be used. The SCM mechanism will keep, at each time, input and/or output data of the corresponding memorization portion, for the last k operating cycles.

According to a significant aspect of the present invention, it is not necessary to back-up all the data determining the circuit state to be able to properly perform the restart. Certain data may be lost for ever without preventing a proper restart. Thus, it is not necessary to back-up the complete state of the circuit at each time. Only data used recently by the memorization portion will require a back-up. Due to this remark, the integration of the SCM mechanisms within the circuit takes up but a small memorization space to back-up the states necessary for the restart, the back-up may be performed continuously, and short-term restarts may be provided. These advantages cannot be obtained if the back-up and the restart are performed at the system level.

For transitory faults, the restart will enable their correction since they will not appear a second time due to their transitory nature. However, for time faults, the repeating of the same operations will result in most cases in the appearing of the time fault during the restart, since this fault is due to permanent causes (circuit delay exceeding the clock period). Thus, according to an aspect of the present invention, if there appears that, after a restart, an error occurs again, the rate of the general system clock will be slowed down to ensure that the failing circuit will have time to operate properly. Of course, those skilled in the art will be able to use other solutions, for example, systematically after each restart slowing down the clock rate to be sure to repair transitory faults as well as time faults.

Finally, a circuit controlling the restart interruption will be used. Its function is to control the switching from the normal operation to the restart operation in case of a fault detection, the switching to the normal operation at the end of the restart procedure, and the switching between the regular memorization resources and the SPM memorization resources.

The present invention also provides various modes for implementing fault immunization or error avoidance mechanisms adapted, for example, to circuits controlling long-term memories.

To achieve these objects, the present invention more specifically provides a digital circuit architecture comprising combinatory circuits, short-term memory circuits unable to store data for more than k operating cycles, long-term memories capable to store data for more than k circuit operating cycles, comprising distinct systems of protection against disturbances for the different circuit types and according to the functionality of these circuits:

a) for long-term memorization circuits, fault-immunization means are used;

b) for short-term memorization circuits, error detection and restart mechanisms are used;

c) for combinatory circuits controlling short-term memories and/or only determining data to be written into long-term memories, error-detection and restart systems are used in the concerned memories.

According to an embodiment of the present invention, some of the combinatory circuits likely to provide control instructions to long-term memories are protected by an avoidance mechanism for the errors of a polarity, and possibly a mechanism for detecting the errors of the opposite polarity.

The foregoing objects, features, and advantages of the present invention will be discussed in detail in the following non-limiting description of specific embodiments in connection with the accompanying drawings.

### BRIEF DESCRIPTION OF THE DRAWINGS

FIG. 1 shows the general structure of a complex digital circuit; and

FIGS. 2 to 12 illustrate as an example only various embodiments of error avoidance mechanisms according to the present invention.

### DETAILED DESCRIPTION

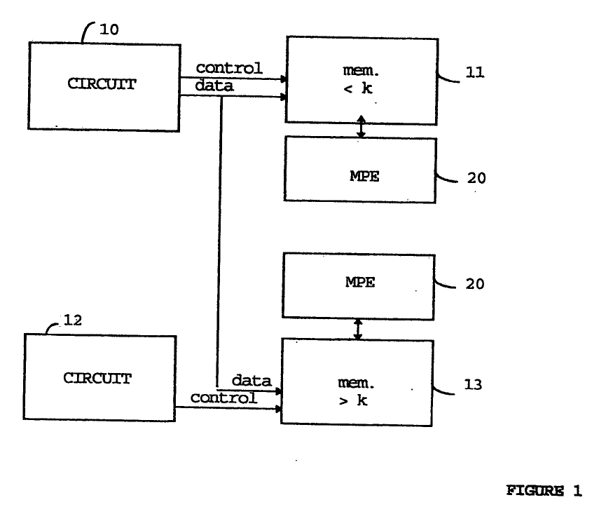

As shown in FIG. 1, according to an aspect of the present invention, a complex digital circuit is divided into various blocks which are logically grouped according to their functionalities and their associations with memories. Four main groups of elements are distinguished in a complex digital circuit. Each group corresponds to one or several integrated circuits or to one or several integrated circuit portions.

A first group 10 comprises combinatory circuits which are either pure combinatory circuits which do not specifically act on memories, or combinatory circuits likely to act on short-term memories or other memorization elements (latches) in which data stored for more than k operating cycles cannot be found, or yet combinatory circuits providing data and not control signals to long-term memorization elements.

A second group 11 comprises short-term memorization elements unlikely to contain data stored for more than k operating cycles.

A third group 12 comprises combinatory circuits likely to provide control signals to memories capable to store data for more than k operating cycles.

A fourth group 13 comprises long-term memorization elements capable to store data for more than k operating cycles.

For combinatory portions 10 and memories 11, and error-detection and restart process may be used. In such a process, one or several state preservation mechanisms 20 save data entering or coming out of the memorization parts in the last k operating cycles. The value of k will be chosen by the designer who will thus select memorization elements 11 and memorization elements 13 taking into account the system response time after the occurrence of a fault, to ensure that, after the error detection, it can generate an interrupt within a time shorter than the duration of the number of memorized operations. In practice, this detection and restart system is the least bulky and the least surface-consuming system in a circuit. Long-term memories will also be associated with a state conservation mechanism backing-up data from among the data of, the last k cycles to enable a restart in case of an error detection in a combinatory element writing data into such memories. Various error detection circuits are known in prior art, especially such as discussed by the present inventor in the above-mentioned patent application.

Regarding the combinatory portions 12 likely to provide control signals (addressing, read/write . . . ) to long-term memories and such long-term memories 13, the previously-described error-detection and restart technique will generally be inefficient since old data could be irremediably lost. Circuits intrinsically or logically immunized against faults will thus be provided. However, as noted hereabove, certain errors may be repaired by techniques of error detection and restart type, especially addressing or read/write errors of a given polarity.

The SRAM and DRAM memory blocks used in electronic circuits most often are memories that can store information for a long time and correspond to the fourth group. However, the latches of a circuit generally are, as mentioned hereabove, short-term memories (second group) that renew their content at each clock pulse. However, some latches may be provided with a state hold control function, such that the latch content is unchanged as the hold control function is activated. The latch then becomes, during the activation of the hold function, a long-term memory and will be processed as an element of the fourth group. A fault-immunization mode then is to duplicate the latch and, when an error is detected on the latch and the hold signal is activated, to use the duplicated latch to restore the latch content. Further, the latch control signals may be protected by a fault-immunization means.

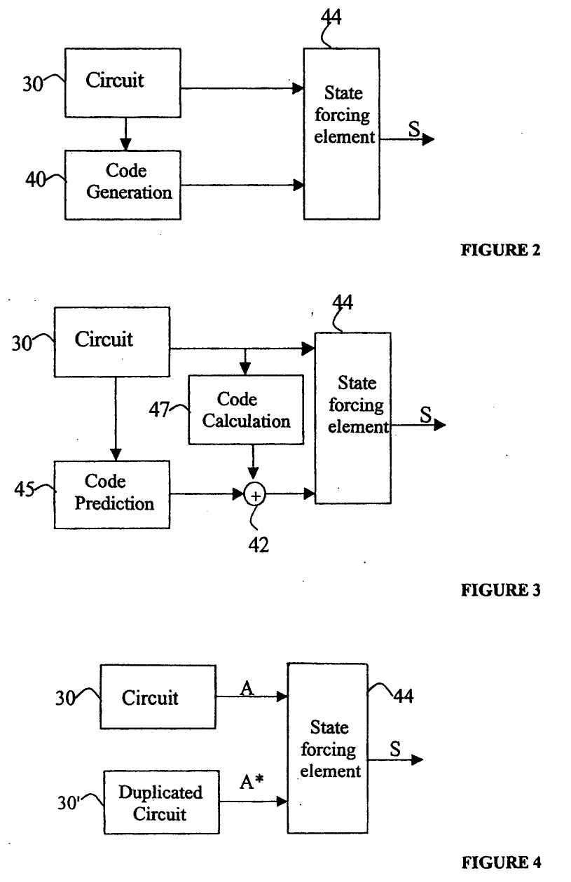

The present invention further provides various embodiments of fault-immunization or error-avoidance circuits which will be described in relation with FIGS. 2 to 12.

In FIG. 2, a mechanism for avoiding errors of a polarity for a combinatory logic circuit 30 having at least one output comprises a circuit for generating an error control code 40 for said output and a state forcing element 44 arranged at said output, controlled by the control code generation circuit 40 to be transparent when the control code is correct, and to force said output to a predetermined state, corresponding to an error polarity opposite to the error polarity that the circuit must avoid, when the control code is incorrect.

According to an embodiment of the present invention, the error control code generation circuit of the error-avoidance mechanism generates an error detection output that takes value 1 (0) to indicate the occurrence of an error and value 0 (1) to indicate the correct operation, and said state-forcing element is an OR (AND) gate having one of its inputs connected to the output of the combinatory circuit and its other inputs connected to the error-detection output of the error control code generation circuit 40, so that when the output of the error control code generation circuit indicates the occurrence of an error, the output of the state-forcing element takes the value 1 (0) corresponding to said predetermined state, and when the output of the error control code generation circuit indicates the correct operation, the output of the state-forcing element takes the same value as the output of the combinatory logic circuit.

In FIG. 3, an error control code generation circuit of the error avoidance mechanism for a combinatory logic circuit 30 comprises a code prediction circuit 45 that calculates an error-detection code (such as a parity bit) for the outputs of the combinatory circuit based on signals other than the combinatory circuit output, a code-calculation circuit 47 that calculates the error detection code from the outputs of the combinatory circuit, and a circuit 42 for checking the error-detection code generated by the prediction circuit and the error-detection code generated by the calculation circuit.

In a circuit of the type in FIG. 3, an error detection signal is obtained at the output of circuit 42. The use of this signal is here described in the context of an error-avoidance process. This signal may also be used to control a restart.

In FIG. 4, the error control code generation of the error-avoidance mechanism for a combinatory logic circuit 30 comprises a duplicated combinatory logic circuit 30′, state forcing element 44 being provided to be transparent when the outputs of the combinatory logic circuit and of the duplicated combinatory logic circuit are identical and, when these outputs are distinct, to output a predetermined state.

In this embodiment of the present invention, the state-forcing element is an OR (AND) gate so that, in the absence of an error, the output of the state-forcing element takes the same value as the combinatory circuit outputs.

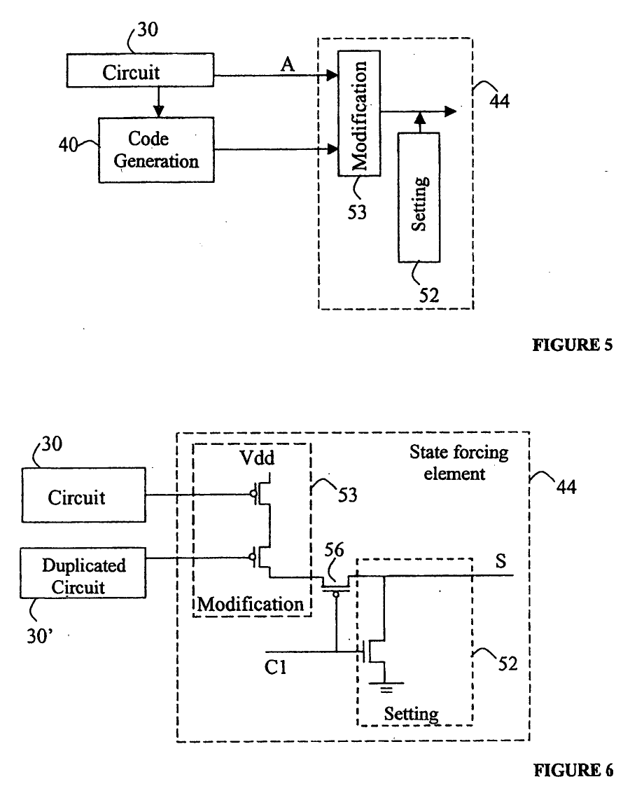

In FIG. 5, state-forcing element 44 of the error-avoidance mechanism for a combinatory logic circuit 30 comprises a setting device 52 previously and systematically setting the output of the state-forcing element to said predetermined state, and a modification device 53, which then modifies the value of this output only if the control code provided by the error control code generation circuit 40 is correct and said predetermined state is different from the value provided at the output of said combinatory logic circuit.

According to this embodiment of the present invention, the error control code circuit comprises a duplicated combinatory logic circuit, said state-forcing element is formed of a setting device previously and systematically setting the output of the state-forcing circuit to the so-called predetermined state, and a modification device that subsequently modifies the output value, only if the corresponding outputs of the combinatory logic circuit and of the duplicated logic circuit have identical values and said predetermined state is different from the state corresponding to the output values of the combinatory logic circuit.

In FIG. 6, the error control code generation circuit of the error-avoidance mechanism for a combinatory logic circuit 30, comprises a duplicated combinatory logic circuit 30′. Modification device 53 is formed of two series-interconnected transistors which connect the output of the state-forcing circuit to voltage Vdd (Gnd) and which are respectively controlled by the output of combinatory logic circuit 30 and by the output of duplicated combinatory logic circuit 30′. Setting device 52 is formed of a switch that connects the output to voltage Gnd (Vdd) when a control signal C1 is active, the control signal being activated for one period of the operating cycle called the setting phase. Optionally, to reduce the consumption of this circuit, a switch 56 is used to disconnect the output of the state-forcing circuit from the output of the modification circuit when control signal C1 is active.

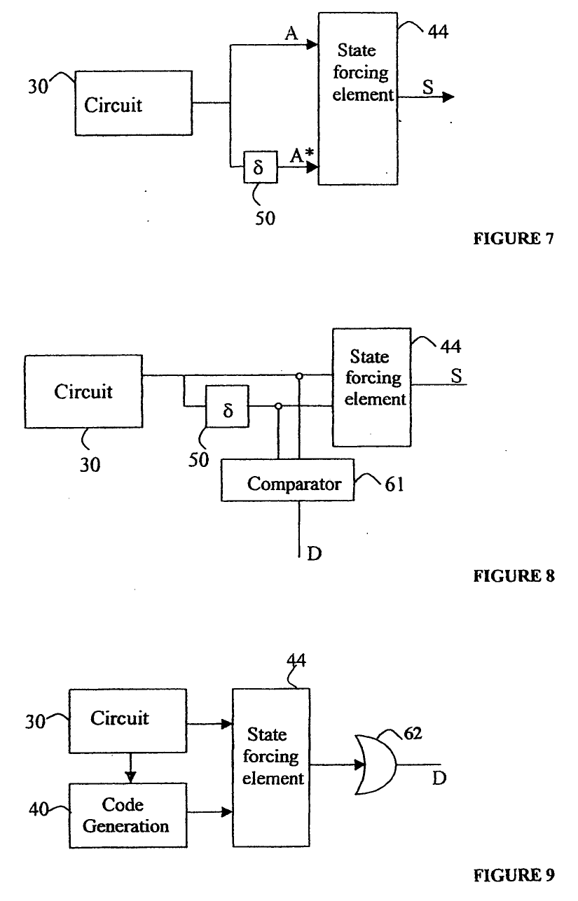

In FIG. 7, the error control code generation circuit of the error-avoidance mechanism for a combinatory logic circuit 30 comprises a delay element 50 that delays the output of the combinatory logic circuit by a predetermined duration δ greater than the maximum duration of transitory errors. State-forcing element 44 is provided to be transparent when the outputs of the combinatory logic circuit and of the delay element are identical, and to generate at its output a predetermined state, when these outputs are different.

In FIG. 8, the error-avoidance mechanism for a combinatory logic circuit 30 is combined with an error detection circuit 61 enabling initiating a restart of the most recent operations. For an error-avoidance mechanism that comprises a delay element 50 and a state-forcing element 44, the error-detection circuit may be formed by a comparator which signals an error when the outputs of combinatory logic circuit 30 and of delay element 50 are distinct for a portion of the operating cycle having a duration longer than a given threshold.

For an error-avoidance mechanism that comprises a duplicated combinatory logic circuit 30′ and a state-forcing element 44, the error-detection circuit may be formed by a comparator 61 which signals an error when the outputs of the combinatory logic circuit and of the duplicated combinatory logic circuit are distinct for a period of the operating cycle having a duration longer than a given threshold.

Apart from the examples of embodiment of the error-detection circuit, there are other possible embodiments for this circuit. For example, a memory decoder generates a plurality of outputs, a single one of which takes value 1 at each cycle of the memory operation. The decoder may be protected by an error-avoidance circuit to avoid for an error of 1-instead-of-0 type (polarity error 1) to occur on a decoder output, which would result in the selection of a memory word that should not be selected. A circuit for avoiding errors of 1-instead-of-0 type will ensure that this error may not occur. It is not necessary, especially if the decoder has a large number of outputs, to correct errors of 0-instead-of-1 type. It may however be provided to detect them to active a restart cycle. This last type of errors results in the situation where all decoder outputs are equal to 0. To detect such errors, a circuit that signals an erroneous operation when a number of decoder outputs different from 1 takes value 1 may be used. This circuit enables detecting the errors of both types on the decoder outputs. A simpler circuit only enabling detection of errors of 0-instead-of-1 type (which here are the errors of interest) consists of an OR logic gate.

Thus, in FIG. 9, combinatory logic circuit 30 provides a plurality of the outputs protected by a plurality of state-forcing elements 44. Said predetermined state is 0 (1). In the absence of errors, a single output of the state-forcing elements takes value 1 (0). The error-detection circuit is an OR (AND) logic gate 62 that signals the occurrence of an error when all the outputs of the state-forcing elements are equal to 0 (1) for a period of the operating cycle that has a duration longer than a given threshold.

In certain circuits, some errors are dangerous only during certain operating cycles. For example, in a memory, errors of 1-instead-of-0 type on the decoder output are dangerous only in a write cycle. Thus, a delay element used in the error circuit may be short-circuited in a read cycle to avoid the operating speed decrease induced by the delay element.

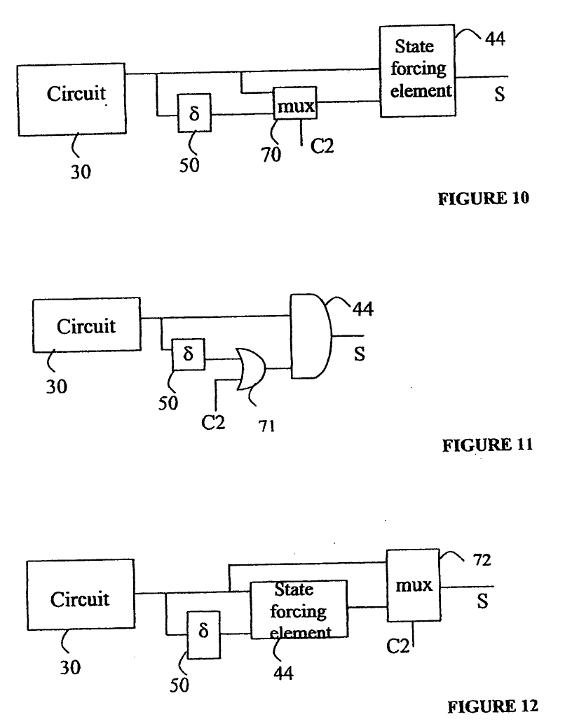

Thus, in FIG. 10, the error-avoidance mechanism comprises a delay element 50 of a predetermined duration greater than the maximum duration of transitory errors and a state-forcing element 44, the circuit also comprise a branching element (mux) 70, enabling bypassing the delay element when a control signal C2 is active. The state-forcing element is provided to be transparent when the outputs of the combinatory logic circuit and of the delay element are identical, and to generate at its output a predetermined value when said outputs are distinct.

In FIG. 11, the error-avoidance mechanism comprises a delay element 50 of a predetermined duration greater than the maximum duration of transitory errors, a branching circuit 71 enabling forcing the output of the delay element to value 1 when a control signal C2 is equal to 1, and a state-forcing element 44 formed by an AND gate having an input connected to the output of combinatory logic circuit 30 and another input connected to the output of circuit 71.

In FIG. 12, the error-avoidance mechanism comprises a delay element 50 and a state-forcing element 44. The circuit also comprises a branching circuit 72 enabling bypassing the state-forcing element when a control signal C2 is active. The state-forcing element is provided to be transparent when the outputs of the combinatory logic circuit and of the delay element are identical, and to generate at its output a predetermined value when said outputs are distinct.

Of course, the present invention may have various alterations, modifications, and improvements which will readily appear to those skilled in the art. In particular, account may be taken of various specific cases in which it will be possible to use a detection and restart mechanism rather than provide elements intrinsically immunized against faults.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A digital circuit architecture comprising a combinatory circuit controlling long-term memory circuits, wherein at least some output bits of said combinatory circuit are protected by an error avoidance mechanism for avoiding errors only for bits of a first value, and not for bits of an alternate value, such as a 0 if the first value is a 1 or such as a 1 if the first value is a 0.

2. The digital circuit architecture of claim 1, further comprising an error detecting mechanism for detecting errors for bits of the alternate value, such as a 0 if the first value is a 1 or such as a 1 if the first value is a 0.

3. The digital circuit architecture of claim 2, wherein said error avoidance mechanism comprises a circuit for generating an error-control code for outputs of a combinatory circuit, and a state-forcing element arranged at the outputs of the combinatory circuit, controlled by the circuit for generating an error-control code to be transparent when an error-control code is correct, and controlled by the circuit for generating an error-control code to force its outputs to a predetermined state, corresponding to an error on a bit of said alternate value, when the error-control code is incorrect.

4. The digital circuit architecture of claim 3, wherein the circuit for generating an error-control code generates an error detection output that takes value 1 to indicate an occurrence of an error and value 0 to indicate a correct operation, and said state-forcing element is an OR gate having an output connected to the output of the combinatory circuit and another input connected to an error-detection output of the circuit for generating an error-control code, so that when the error-detection output of the circuit for generating an error-control code indicates an occurrence of an error, an output of the state-forcing element takes value 1 corresponding to said predetermined state and, when the output of the circuit for generating an error-control code indicates a correct operation, the output of the state-forcing element takes the same values the output of the combinatory circuit.

5. The digital circuit architecture of claim 3, wherein the circuit for generating an error-control code comprises a prediction circuit that calculates an error-detection code for the outputs of the combinatory circuit based on signals other than the outputs of the combinatory circuit, a calculation circuit which calculates an error-detection code from the combinatory circuit outputs, and a checking circuit for checking the error-detection code generated by the prediction circuit and the error-detection code generated by the calculation circuit.

6. The digital circuit architecture of claim 3, wherein the circuit for generating an error-control code comprises a duplicated combinatory circuit, said state-forcing element being provided to be transparent when outputs of the combinatory circuit and outputs of the duplicated combinatory circuit are identical, and the state-forcing element to generate at its output a predetermined state when said outputs of the combinatory circuit are not identical to the outputs of the duplicated combinatory circuit.

7. The digital circuit architecture of claim 3, wherein the state-forcing element comprises a setting device previously and systematically setting an output of the state-forcing element to said predetermined state, and a modification device which subsequently modifies the value of the output of the state-forcing element only if the error-control code is correct and said predetermined state is different from the state corresponding to the output value of the combinatory circuit, wherein the output of the state-forcing element is set to correspond to the state of the output value of the combinatory circuit.

8. The digital circuit architecture of claim 3, wherein the circuit for generating an error-control code comprises a delay element capable of delaying the outputs of the combinatory circuit by a predetermined duration greater than a maximum of transitory disturbances, the state-forcing element being configured to be transparent when the outputs of the combinatory circuit and outputs of the delay element are identical, and the state-forcing element configured to output a predetermined state when said outputs of the combinatory circuit are not identical to the outputs of the delay element.

9. The digital circuit architecture of claim 6, wherein the error detecting mechanism for detecting errors on bits of said alternate value comprises a comparator which signals an error when the outputs of the combinatory circuit and the outputs of the circuit for generating an error-control code are different for duration longer than a given threshold.

10. The digital circuit architecture of claim 3, wherein the combinatory circuit provides a plurality of outputs protected by a plurality of state-forcing elements, said predetermined state is 0, in the absence of errors, a single one of the outputs of the state-forcing element takes value 1, and the error detecting mechanism for detecting errors on bits of said alternate value comprises an OR logic gate which signals occurrence of an error when all outputs of the plurality of state-forcing elements are equal to 0 for a duration longer than a given threshold.

11. The digital circuit architecture of claim 3, wherein, during an operating phase and when a control signal is active, the error-avoidance mechanism is short-circuited by a branding circuit, which imposes on the output of the error-avoidance mechanism the value of the output of the combinatory circuit as directed by the active control signal.

12. The digital circuit architecture of claim 9, wherein the circuit for generating an error-control code generates an error detection output that takes value 0 to indicate occurrence an error and value 1 to indicate a correct operation, and said state-forcing element is an AND gate having an input connected to the output of the combinatory circuit and another input connected to an error-detection output of the circuit for generating an error-control code, so that when the error-detection output of the circuit for generating an error-control code indicates an occurrence of an error, an output of the state-forcing element takes value 1 corresponding to said predetermined state and, when the error-detection output of the circuit for generating error-control code indicates a correct operation, the output of the state-forcing element takes the same value as the output of the combinatory circuit.

13. The digital circuit architecture of claim 9, wherein the combinatory circuit provides a plurality of outputs protected by a plurality of state-forcing elements; said predetermined state is 1; in an absence of errors, a single one of the outputs of the state-forcing element takes value 0; and the error detecting mechanism for detecting errors on bits of said alternate value comprises an AND logic gate which signals occurrence of an error when all outputs of the plurality of state-forcing elements are equal to 1 for a duration longer than a given threshold.
